(19) United States
(12) Patent Application Publication
(10) Pub. No.: US 2005/0191782 A1
(43) Pub. Date: Sep. 1, 2005

(54) PMOS TFT including lightly doped drain region and method of fabricating the same

(76) Inventors: Tae-Hoon Yang, Seongnam-si (KR); Kyu-Hwan Choi, Seongnam-si (KR); Sung-Sik Bae, Yongin-si (KR)

Correspondence Address: MCGUIREWOODS, LLP, 1750 TYSONS BLVD, SUITE 1800, MCLEAN, VA, 22102, US

(21) Appl. No.: 11/060,574

(22) Filed: Feb. 17, 2005

(30) Foreign Application Priority Data
Feb. 17, 2004 (KR) 2004-10489

(51) Int. Cl. H01L 21/00; H01L 21/84

(52) U.S. Cl. 438/30

(57) ABSTRACT

A PMOS thin film transistor including an LDD region may be fabricated by implanting an ion dose at a specific concentration in order to form the LDD region with a certain range of sheet resistance at both ends of a gate electrode of the PMOS thin film transistor. A buffer layer, an active layer, the gate insulating layer and a gate electrode may be sequentially formed on the substrate of the transistor.

### CROSS-REFERENCE TO RELATED APPLICATION

This application claims priority to and the benefit of Korean Patent Application No. 2004-10489, filed Feb. 17, 2004, which is incorporated herein by reference in its entirety.

### BACKGROUND OF THE INVENTION

1. Field of the Invention

The present invention relates to a PMOS thin film transistor and method of fabricating the same in which an ion dose of an impurity may be implanted (while forming an LDD region) in an amount to reduce OFF current of a PMOS thin film transistor. The LDD region formed may have a specific range of sheet resistance.

2. Description of the Related Art

As semiconductor technology has advanced, miniaturization has created increasingly high speed and low power consumption devices for several decades. Recently, semiconductor devices have become highly integrated, and thus thin film transistors are primarily used.

A thin film transistor generally includes a semiconductor layer; gate, source and drain electrodes. This is typically implemented by the semiconductor layer including source and drain regions and a channel region interposed between the source and drain regions. As miniaturization has progressed, the space between the source and drain regions formed in the semiconductor layer has become narrower and the channel length has become shorter.

One of the problems frequently generated in these transistors is hot carrier instability. As the hot carriers are generated due to a high electric field between the source and the drain, the carriers (electrons or holes) around the drain region are injected into a gate electrode or a substrate. Accordingly, the gate oxide may gain an electric charge and the threshold voltage may become unstable. This may lead to serious degradation in reliability of the fabricated semiconductor device.

Forming a lightly doped region can help to suppress hot carrier effect (HCE), which is a type of short channel effect (SCE). Hot carrier effect is a phenomenon that appears as the channel length becomes shorter. Carriers having high energy due to a rapidly increased voltage between the drain region and the channel region in driving the thin film transistor are referred to as hot carriers. The hot carriers can be injected into the gate oxide layer damaging the gate oxide layer and creating a trap in it. This can degrade the thin film transistor.

Thus, rapid increase in voltage can be blocked, thereby preventing formation of hot carriers by forming a lightly doped region between the channel region and the source and drain regions. Moreover, as the concentration of the activated impurities in the lightly doped region decreases, hot carrier effect is further suppressed.

To address the foregoing problems and obtain sufficient characteristics of the transistor (high saturated current), various schemes have been proposed in the transistor device structure aspects, one of which is a lightly doped drain (hereinafter, referred to as “LDD”). This can be a structure that includes a light doped region formed between the source and drain regions (which may be heavily doped regions) of the silicon thin film transistor and the channel region. With such an LDD structure, the resultant OFF current can be reduced, and both leakage current (that induces spots or stains) and ON current (that controls EL characteristics) may be effectively controlled.

The introduction of the LDD structure as stated above may minimize the hot carrier effect because there is no problem of diffusion of the impurities in a parallel direction or a perpendicular direction [E. Takeda et al, IEEE Transactions on Electron Devices, ‘Submicrometer MOSFET Structure for Minimizing Hot-Carrier Generation’ ED, 29, 4, p 611-618]. LDD structure in connection with an n channel device (NMOS) has been extensively studied. It is NMOS devices that have the greatest hot carrier problem. However, introducing LDD structure into a p channel device (PMOS) has also been studied.

U.S. Pat. Nos. 5,717,237 and 5,585,286 discuss a method of fabricating a PMOS device having an LDD structure, wherein p type boron ions are implanted at doses from about 3E14 to about 1E12 atoms/cm² to get the LDD effect.

Further, U.S. Pat. No. 5,962,870 discloses a method of fabricating a PMOS semiconductor device, with a concentration of the p type boron ions from about 1E20 to 5E21 atoms/cm³ in volume to get the LDD effect. When calculated in terms of area, that is 5E11 to 2.5E13 atoms/cm², which refers to the concentration of activated boron ions. The ion dose implanted to get such a value is typically larger than the target value.

All patents listed above propose impurity ions, dose and the like, in connection with forming a LDD in a PMOS. However, they just indicate that the drain-source punch-through current and the short channel may be prevented by including the LDD—the LDD effect is not experimentally and explicitly proven and an extremely high dose range is presented therein. However, when the implanted ion dose is decreased, a parasitic resistance between the source region and the drain region (a parasitic channel resistance) may increase, rapidly degrading the performance of the thin film transistor or the ON current.

### SUMMARY OF THE INVENTION

The present invention, therefore, may help to solve the aforementioned problems associated with conventional devices by providing a PMOS thin film transistor including an LDD region in which hot carrier effect is suppressed. The present invention also can provide a PMOS thin film transistor including an LDD wherein the LDD region is formed to reduce OFF current.

The present invention also can provide a PMOS thin film transistor including an LDD that indicates a dose of impurity ions with a specific range to form an LDD region. The present invention also can provide a PMOS thin film transistor including an LDD region that has a specific range of sheet resistance and method of fabricating the same. The present invention can also provide a method of fabricating each of the above transistors.

One exemplary embodiment of the present invention provides a PMOS thin film transistor including a semiconductor layer having source and drain regions, and a channel region interposed between the source and drain regions. The semiconductor layer includes a lightly doped drain (LDD) region interposed between the source and drain regions and the channel region, and has a sheet resistance of about 50 to about 110 kΩ/□.

Another exemplary embodiment of the present invention provides a method of fabricating a PMOS thin film transistor including providing a substrate on which a semiconductor layer, a gate insulating layer and a gate electrode layer are formed; implanting first p type impurity ions into both sides of the semiconductor layer to form heavily doped source and drain regions; and implanting second p type impurity ions into a selected region in the heavily doped source and drain regions at a dose of about 2.6E13 to about 6E13 atoms/cm² to form a lightly doped drain region.

A PMOS thin film transistor of the present invention may be preferably used in a flat panel display device such as an active matrix type liquid crystal display device or an active matrix type organic electroluminescence display device.

### BRIEF DESCRIPTION OF THE DRAWINGS

FIGS. 1A and 1B are cross-sectional views illustrating a structure of a PMOS transistor having an LDD region.

FIGS. 2A and 2B are graphs showing change of ion mobility with respect to an LDD length when impurity ions are implanted at doses of about 6E13 atoms/cm² and about 3E13 atoms/cm² in accordance with an example of the present invention.

FIGS. 3A to 3C are graphs showing change of a drain current with respect to a gate voltage when impurity ions are implanted at a dose of about 6E 13 atoms/cm² in accordance with another example of the present invention, wherein FIG. 3A, FIG. 3B, and FIG. 3C are respectfully measured in drain voltages of 0.1V, 5.1V and 10.1V.

FIGS. 4A to 4C are graphs showing change of a drain current with respect to a gate voltage when impurity ions are implanted at a dose of about 3E13 atoms/cm² in accordance with yet another example of the present invention, wherein FIG. 4A, FIG. 4B and FIG. 4C are respectively measured in drain voltages of 0.1 V, 5.1 V and 10.1V.

FIGS. 5A and 5B are graphs showing a change of the maximum OFF current with respect to an LDD length when impurity ions are implanted at doses of about 6E13 atoms/cm² and about 3E13 atoms/cm² in accordance with an example of the present invention.

FIG. 6 is a graph showing a change of sheet resistance Rs in the LDD region when impurity ions are implanted at a dose of about 1E15 to about 3E13 atoms/cm² in accordance with an example of the present invention.

### DETAILED DESCRIPTION OF THE INVENTION

The present invention will now be described more fully with reference to the accompanying drawings, in which exemplary embodiments of the invention are shown. This invention may, however, be embodied in different forms and should not be construed as limited to the embodiments set forth herein. In the drawings, the thickness of layers and the sizes of regions are exaggerated for clarity. Like numbers refer to like elements throughout the specification.

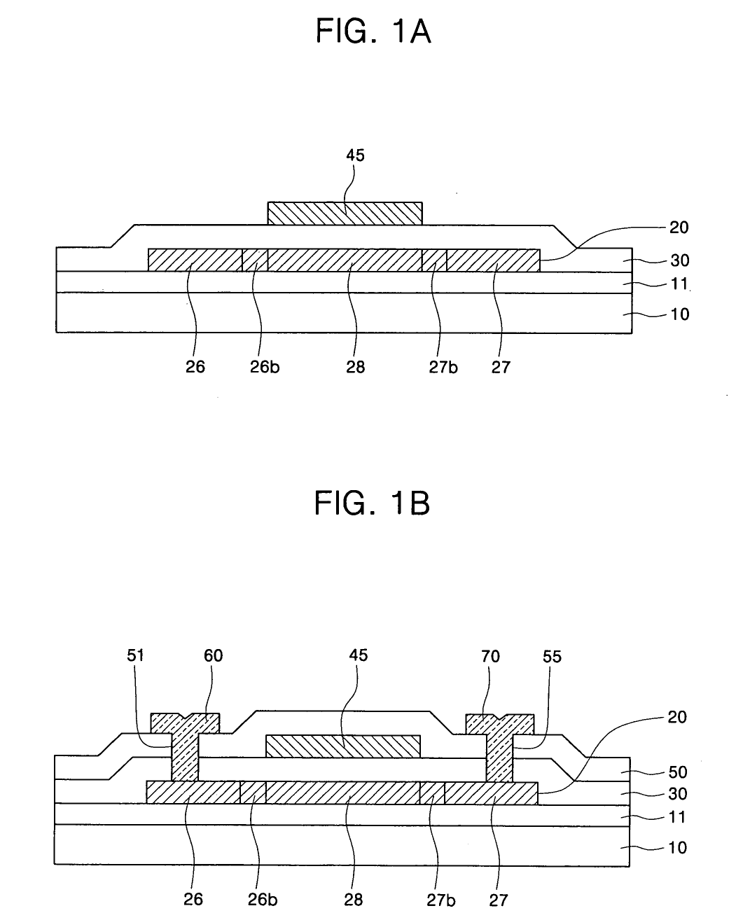

As shown in FIGS. 1A and 1B, the buffer layer 11 may be a layer for protecting a thin film transistor to be formed in the subsequent process from impurities diffused out from the insulating substrate 10. It may be formed of a silicon nitride (SiNₓ) layer or a silicon oxide (SiO₂) layer.

Next, an amorphous silicon layer or a polysilicon layer may be formed on the buffer layer 11, and may then be patterned to form an island-type semiconductor layer 28.

A gate insulating layer 30 covering the semiconductor layer 20 may be formed of a silicon nitride (SiNₓ) layer or a silicon oxide (SiO₂) layer all over the insulating substrate 10.

A gate electrode material may be deposited on the gate insulating layer 30 and may then be patterned to form a temporary gate electrode. The gate electrode layer may be made to cover LDD regions 26b and 27b. The gate electrode material may be any metal (or metal substitute) typically used in the art. For example, it may be formed of Al, Cr, Co, Ir, Mn, Ni, Pd, Pt, a mixed metal of W and Mo, or polysilicon.

First impurity ions may be implanted at a high concentration using the temporary gate electrode as a mask to form heavily doped source and drain regions 26 and 27 at both ends of the semiconductor layer 20. The impurity regions (heavily doped source and drain regions 26 and 27) other than the lower region of the temporary gate electrode may be formed in the semiconductor layer 20. A lower region of the temporary gate electrode may be defined as a channel region (or active layer 28). Here, the first impurity ions implanted may be boron ions or compounds including boron, which are typically implanted. The dose of the first impurity ions should naturally be higher than that for forming the second impurity ions in the subsequent process.

Next, a gate electrode 45 may be formed by etching the temporary gate electrode as large as the LDD regions 26b and 27b of the temporary gate electrode to form the LDD regions 26b and 27b. Then the second impurity ions may be implanted into the semiconductor layer 20 using the gate electrode 45 as a mask to form lightly doped drain regions (LDD region, 26b and 27b). These regions may contact the heavily doped source and drain regions 26 and 27 at both ends of the semiconductor layer. The second impurity ions implanted may be boron ions equal to those of the first impurity ions. The dose of the second impurity ions may be lower than that of the first impurity ions from the viewpoint of characteristics of the LDD region 26b and 27b. The second impurity ions implanted herein may be typically implanted boron ions or compounds including boron.

In particular, it may be desirable that the dose of the second impurity ions proposed in the present invention be about 2.6E13 to about 6E13 atoms/cm², which may be about 5.30E18 to 1.20E19 atoms/cm³ in volume. The ion dose may be a value lower than a conventionally proposed value for forming the LDD region, and an LDD effect may begin to show in implanting at a dose less than about 6E13 atoms/cm² proposed in the present invention. Hot carrier effect may be further suppressed due to the low ion dose proposed in the present invention, and a rapid increase in electric field created in the drain region may be avoided due to the low ion doping concentration formed in the LDD region. This may help to stop the generation of hot carriers.

The ion implantation of the first and second impurity ions may be performed by an ion showering method or an ion implantation method.

Next, to activate the implanted impurity ions, an insulating interlayer 50 may be formed on the substrate 10 including the semiconductor layer 20 where the heavily doped source and drain regions 26 and 27, and the LDD regions 26b and 27b are formed. Then heat treatment may be performed at a temperature of about 400 to about 500° C. for about 1 to about 3 hours. As a result, the implanted impurity ions may be activated in the impurity regions 26, 26b, 27 and 27b, producing the LDD effect. The LDD regions 26b and 27b may have a sheet resistance of about 50 to about 110 kΩ/□.

Such an increase of the sheet resistance may mean that current flow flowing through the channel region 28 from the source region 26 to the drain region 27 is not smooth. This may also indicate that the rapid increase in electric field in the drain region 27 may be suppressed and that the generation of hot carriers may also be reduced. This may be accomplished with the ion dose for forming the LDD regions 26b and 27b proposed in the present invention, and may result in a reduction of OFF current of the PMOS thin film transistor.

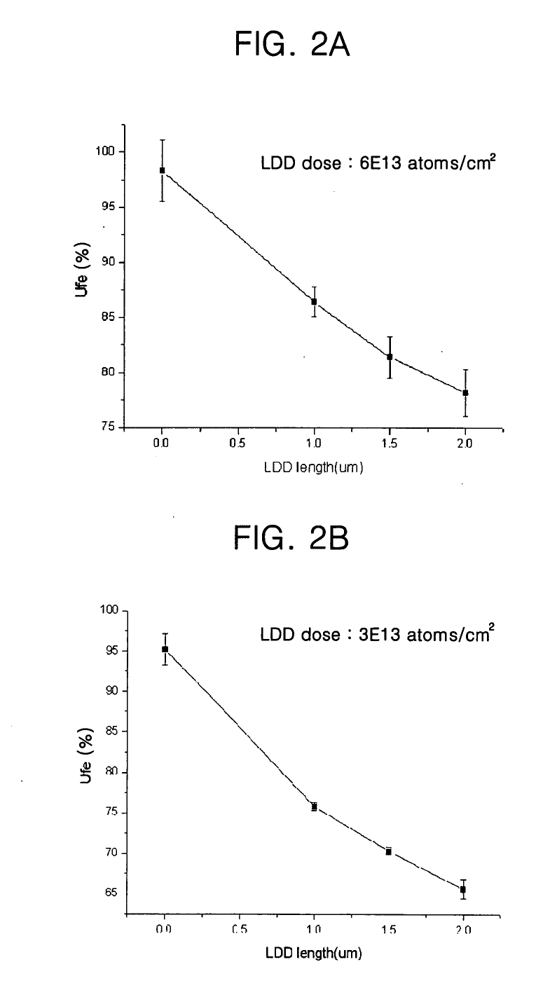

When impurity ions are implanted at doses of about 6E13 atoms/cm² and about 3E13 atoms/cm², the measurement result of ion mobility (FIGS. 2A and 2B) shows that ion mobility is reduced depending on the length of the LDD in the LDD region. Thus ions are activated in the LDD region, producing the LDD effect.

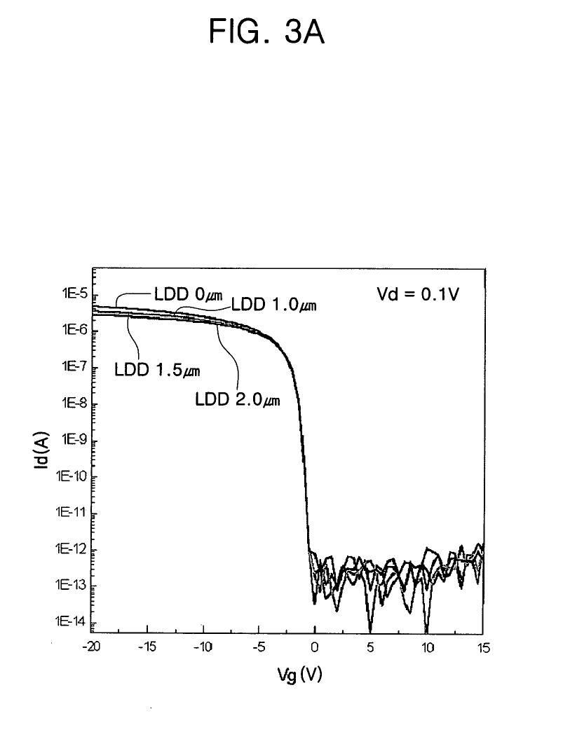

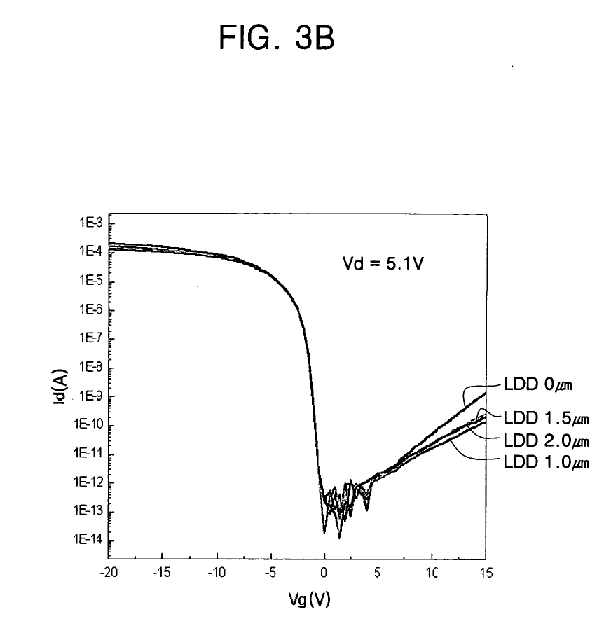

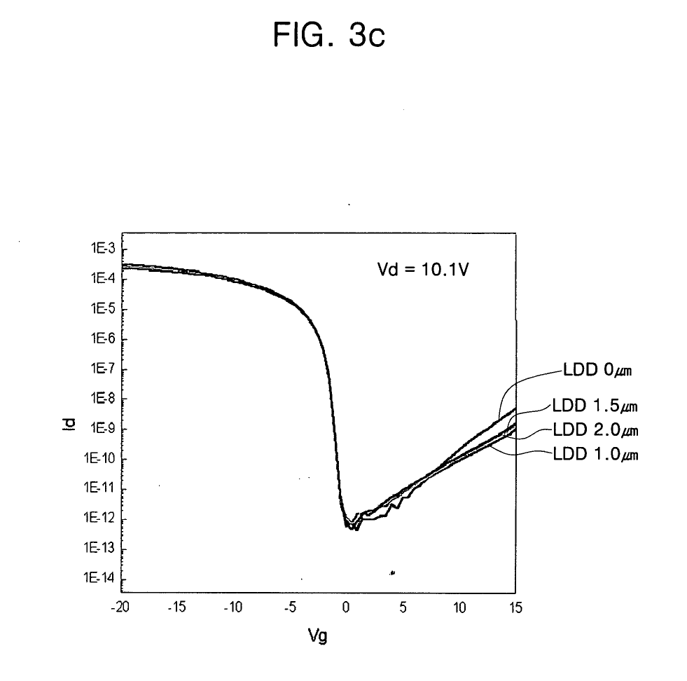

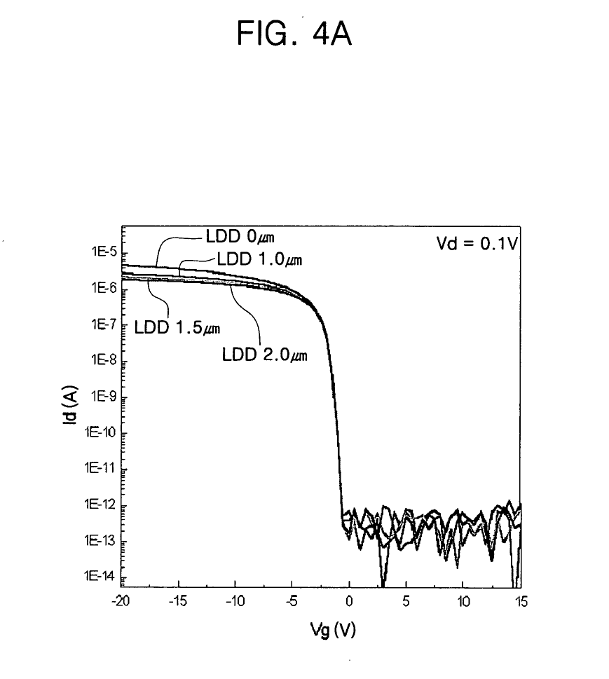

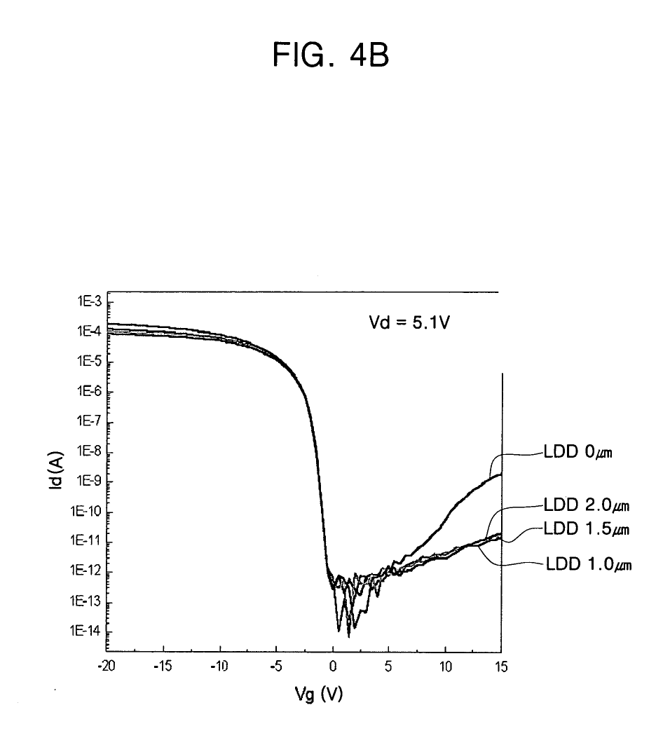

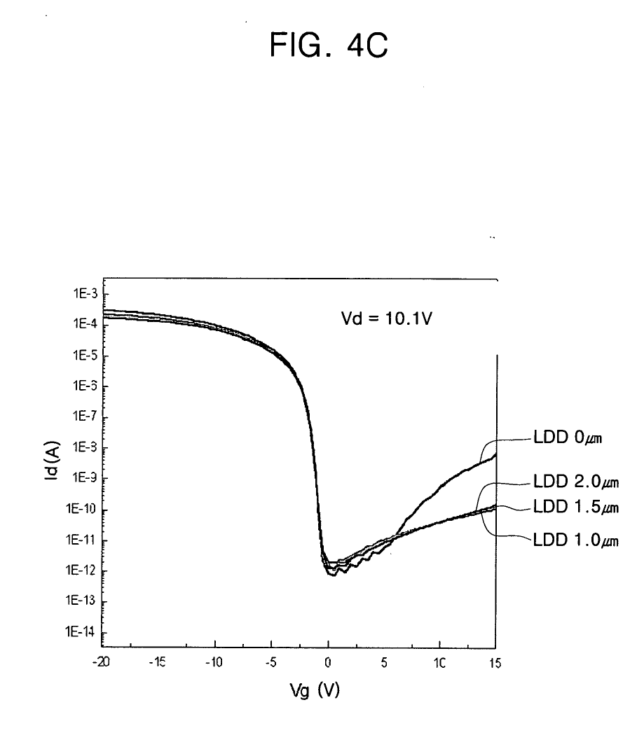

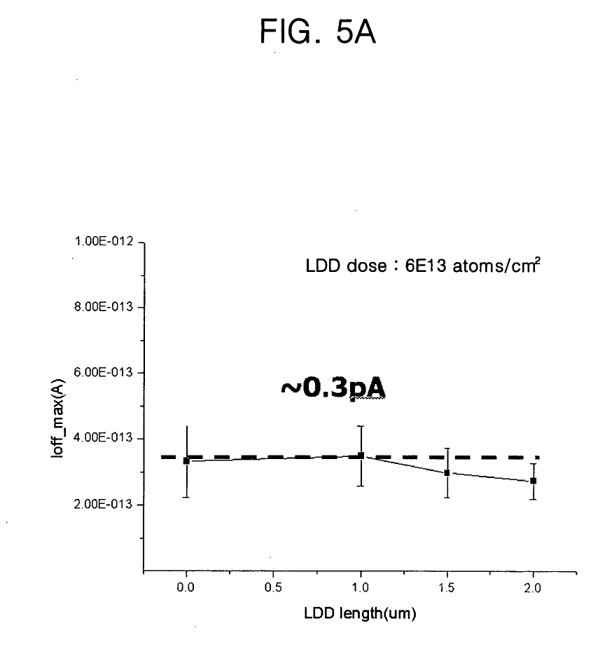

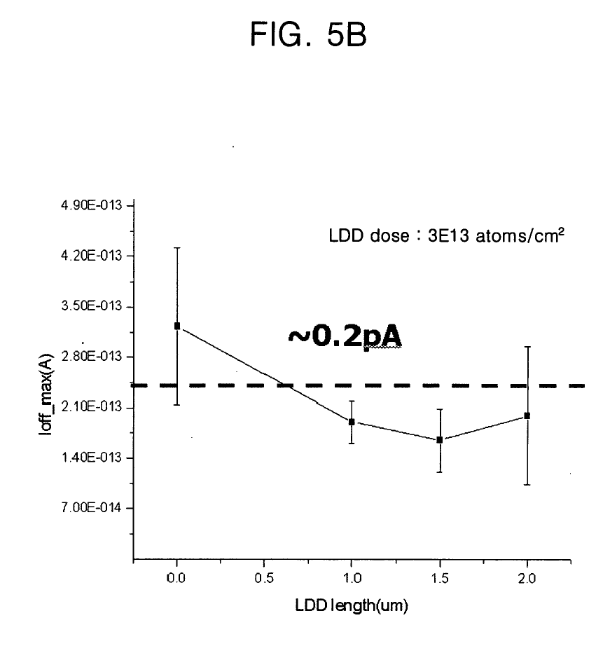

Similarly, when the second impurity ions are implanted at a dose of about 6E13 atoms/cm² or about 3E13 atoms/cm² lower than the above one, OFF current with respect to the gate voltage is significantly reduced, and with this, the effect from the formation of the LDD region may be fully obtained, as shown in FIGS. 3B, 3C, 4B and 4C.

In particular, as shown in FIGS. 3A to 4C, when impurity ions are implanted at doses of about 6E13 atoms/cm² and about 3E13 atoms/cm², it is seen that as the LDD length increases, OFF current decreases. Thus, the optimal length of the LDD may be obtained to minimize OFF current in the design of a thin film transistor.

When the impurity ions are implanted at doses of about 6E13 atoms/cm² and about 3E13 atoms/cm², the sheet resistance has a range of about 50 to about 110 kΩ/□. If the impurity ions are implanted at a dose smaller than the above doses, the sheet resistance may be gradually reduced. A saturated region may appear at a dose of about 1E15 atoms/cm².

Next, a photoresist pattern may be formed on the insulating interlayer 50, and selected regions may then be etched to form contact holes/via holes 51 and 55 that expose the source and drain regions 26 and 27.

Next, a metal electrode material may be deposited all over the substrate such that it covers the contact holes/via holes 51 and 55. It may then be patterned to form source and drain electrodes 60 and 70. This may complete a PMOS thin film transistor having the LDD structure.

In an embodiment of the present invention, for convenience sake, although the LDD region has been described as being formed after the heavily doped region is formed using the gate electrode as a mask. Other methods known in the art may be used to form the heavily and lightly doped regions, and the order of the various steps may also be changed. As an example, the lightly doped region may be formed by covering the gate electrode with a photoresist pattern to include a region corresponding to the lightly doped region, followed by forming the heavily doped region and implanting low concentration impurities. Forming the heavily and lightly doped regions may thus be varied depending on how many masks are formed and where the masks are formed. Such details may be appropriately selected from among the known technologies.

As described above, a PMOS thin film transistor having an LDD region fabricated as taught may have a reduced OFF current with respect to the gate voltage as well as an appropriate drain current because hot carrier effect is suppressed. Such a PMOS thin film transistor may be appropriately applied to an active matrix type flat panel display device including thin film transistors and also to pixels and pixel units.

Examples of the present invention will now be described, which should be construed as illustrative, not restrictive.

### EXAMPLE

1. Change of Ion Mobility

To check whether the dose of the second impurity ions proposed in the present invention shows an LDD effect, ion mobility in the LDD region was measured when the second impurity ions were implanted at doses of about 6E13 atoms/cm² and about 3E13 atoms/cm². Ion mobility was measured with the LDD region not formed and with the LDD region formed with lengths of about 1 μm, about 1.5 μm, and about 2 μm. The results are shown in FIGS. 2A and 2B.

FIG. 2A is a graph showing Ufe with respect to an LDD length when impurity ions are implanted at a dose of about 6E13 atoms/cm². FIG. 2B is a graph showing Ufe with respect to an LDD length when impurity ions are implanted at a dose of about 3E13 atoms/cm².

As shown in FIG. 2A, Ufe was about 98% when the LDD region was not formed, but the value rapidly reduced when the LDD region was formed. As a result, when the length of the LDD region was about 2 μm, Ufe was about 76%, which was reduced by about 22% compared to when the LDD region was not formed. This result was about the same when impurity ions were implanted at a dose of about 3E13 atoms/cm².

As shown in FIG. 2B, Ufe was about 95% when the LDD region was not formed, but the value rapidly reduced when the LDD region was formed. As a result, when the length of LDD region was 2 μm, Ufe was about 66%, which was reduced by about 29% compared to when the LDD was not formed. This reduction of the Ufe in the LDD region indicates that the LDD effect may also be shown with as little ion dose as proposed herein.

2. Change of OFF Current

To check how much the LDD effect is exhibited at the dose of the second impurity ions proposed in the present invention, the gate voltage and the drain current were measured when impurity ions were implanted at doses of about 6E13 atoms/cm² and about 3E13 atoms/cm². This test helped to check whether or not OFF current was generated in the LDD region.

A. When Impurity Ions were Implanted at a Dose of about 6E13 Atoms/cm²

The drain current Id was measured while applying the drain voltage Vd to about 0.1V, about 5.1V and about 10.1V and changing the gate voltage Vg from about −20V to about +15V. The measurement was made while changing the length of the LDD region from about 0.0 to about 2.0 μm. The results are shown in FIGS. 3A to 3C.

As shown in FIG. 3A, there was little change of Id with respect to the length of the LDD at the low voltage of 0.1V. A negligible degree of OFF current flowed through the gate probably because the minority carriers were created in small quantities at the low voltage of 0.1V.

However, as shown in FIGS. 3B and 3C, when a voltage higher than that of FIG. 3A was applied, a high electric field was created in the source and drain regions. Accordingly, as the majority carriers were created, the gate voltage increased.

As shown in FIG. 3B, the PMOS thin film transistor where the LDD region was not formed showed a rapid increase in voltage, while the PMOS thin film transistor where the LDD region was formed showed a small increase in voltage. Such an increased voltage caused an increase of OFF current in driving the PMOS thin film transistor, thus significantly degrading the electrical characteristics of the device.

However, by forming the LDD region, a space charge layer expanded toward both the source and drain regions when the voltage in the source and drain regions was increased by the formed LDD. Thus an increase in electric field across the channel was suppressed. Specifically, when comparing the PMOS thin film transistor that includes a predetermined thickness of LDD with the PMOS thin film transistor that does not include the LDD, drain current Id showed a difference of more than one order at a voltage of 15V. This indicates that the LDD effect appears at the doses proposed in the present invention.

As shown in FIG. 3C, even when a high voltage more than 10.1V was applied, both the drain current Id for the PMOS thin film transistor that does not include the LDD and the drain current Id for the PMOS thin film transistor that includes the predetermined thickness of LDD increased as the gate voltage increased (as in FIG. 3B). On the other hand, for the PMOS thin film transistor that includes the LDD, the amount of increase was smaller than that of the PMOS thin film transistor that does not include the LDD.

B: When Impurity Ions are Implanted at a Dose of about 3E13 Atoms/cm²

The drain current Id was measured while applying the drain voltage Vd to about 0.1V, about 5.1V and about 10.1V, and changing the gate voltage Vg from about −20V to about +15V. The measurement was made while changing the length of the LDD region from about 0.0 to about 2.0 μm, the result of which was shown in FIGS. 4A to 4C. In this experiment, the second impurity ions for forming the LDD region were implanted at a dose of about 3E13 atoms/cm² lower than that of the case A described above.

As shown in FIG. 4A (as in FIG. 3A), there was little change of Id with respect to the length of the LDD at the low voltage of about 0.1V, and this was due to a negligible degree of OFF current flowing through the gate because the minority carriers were created in low quantities at the low voltage of about 0.1V.

However, as shown in FIGS. 4B and 4C (as in FIGS. 3B and 3C), as a voltage of about 5.1V higher than that of FIG. 4A was applied, a high electric field was created in the source and drain regions. Accordingly, as the majority carriers were created, the gate voltage was increased, thereby significantly increasing OFF current as shown in FIGS. 4B and 4C.

As shown in FIG. 4B (as in FIG. 3B), for the PMOS thin film transistor where the LDD region was not formed, OFF current was significantly generated and Id showed a difference of more than two orders (at a gate voltage of about 15V) compared with the PMOS thin film transistor where the LDD region was formed. Thus OFF current of the gate voltage could also be effectively suppressed with the ion dose proposed in the present invention.

As shown in FIG. 4C, even when a high voltage more than about 10.1V was applied, both Id for the PMOS thin film transistor that does not include the LDD and Id for the PMOS thin film transistor that includes a predetermined thickness of LDD increased as the gate voltage increased (as in FIG. 3B). On the other hand, for the PMOS thin film transistor that includes the LDD, the amount of increase was smaller than that of the PMOS thin film transistor that does not include the LDD.

From the above experimental results, the LDD effect that OFF current is reduced in the PMOS thin film transistor could also be obtained with a dose less than about 6E13 atoms/cm² proposed in the present invention.

3. Change of Sheet Resistance

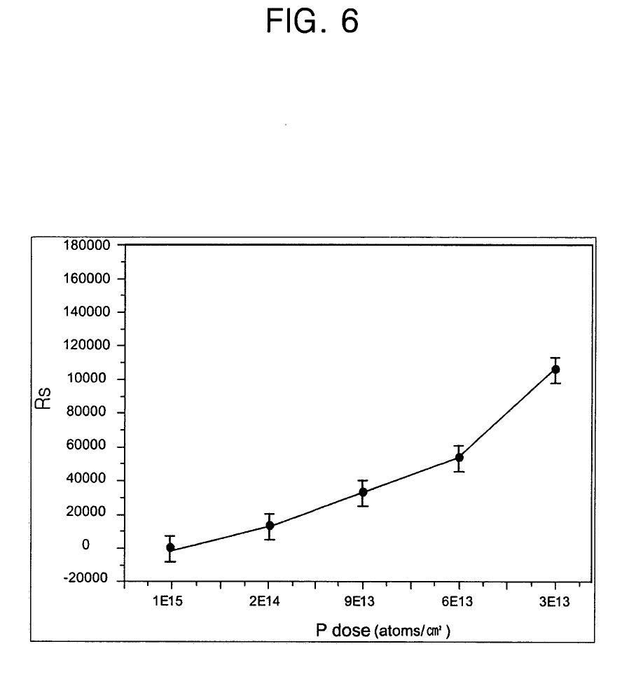

In order to determine the sheet resistance of the LDD region formed at the dose of the second impurity ions proposed in the present invention, the sheet resistance Rs (referred also to as “square resistance”) was measured while boron ions were implanted at a dose of about 1E15 to about 3E13 atoms/cm². The results are shown in FIG. 6.

As shown in FIG. 6, when impurity ions were implanted at doses of about 3E13 and about 6E13 atoms/cm², the sheet resistance showed very large values of about 100 kΩ/□ and about 50 kΩ/□. However, when the impurity ions were implanted at a dose below the above range, the sheet resistance was reduced, and the sheet resistance was measured to be near 0 (saturated region) in the case of about 1E15 atoms/cm². This reduction of sheet resistance indicated that carriers that existed in the source electrode or the channel region, (preferably minority carriers), could easily migrate into the drain electrode side, and thus there was little LDD effect.

As described above, a PMOS thin film transistor having the LDD region may obtain the LDD effect even when impurity ions are implanted at a dose less than about 2.6E13 to about 6E13 atoms/cm² in forming the LDD region. As a result, OFF current of the PMOS thin film transistor may be effectively controlled, and the performance of the thin film transistor may be improved.

Further, the PMOS thin film transistor where the LDD region is formed may be appropriately applied to a conventional flat panel display device such as an active matrix liquid crystal display device (AMLCD) or an active matrix organic electroluminescence display device (AMOLED), and especially to a pixel unit that requires control of OFF current.

Although the present invention has been described with reference to certain exemplary embodiments thereof, changes may be made to the disclosed embodiments without departing from the scope of the invention.

1. A PMOS thin film transistor, comprising:
a semiconductor layer comprising source and drain regions, and a channel region interposed between the source and drain regions,
wherein the semiconductor layer comprises a lightly doped drain (LDD) region interposed between the source and drain regions, and the channel region, and
wherein the LDD region comprises a sheet resistance of about 50 to about 110 kΩ/□.

2. The PMOS thin film transistor of claim 1, wherein the LDD region comprises implanted p type ions.

3. The PMOS thin film transistor of claim 1, wherein the p type ions comprise boron (B) ions.

4. The PMOS thin film transistor of claim 1, wherein the PMOS thin film transistor is adapted to be used in an active matrix liquid crystal display device (AMLCD) or an active matrix organic electroluminescence display device (AMOELD).

5. A method of fabricating a PMOS thin film transistor, comprising:
forming a semiconductor layer, a gate insulating layer, and a gate electrode material layer on a substrate;
implanting first p type impurity ions into the semiconductor layer to form a heavily doped source region and a heavily doped drain region; and
implanting second p type impurity ions into a selected region of the heavily doped source region and a selected region next to the heavily doped drain region, at an ion dose of about 2.6E13 to about 6E13 atoms/cm² to form a lightly doped region.

6. The method of claim 5, wherein the second impurity ions are implanted at an ion dose of about 5.3E18 to about 1.2E19 atoms/cm³ in volume.

7. The method of claim 5, wherein the first impurity ions and the second impurity ions are one selected between a boron ion and a boron compound.
